(19) United States
(12) Patent Application Publication
(10) Pub. No.: US 2007/0268731 A1
(43) Pub. Date: Nov. 22, 2007

(54) Layout compiler

(75) Inventors: Larg H. Weiland, Livermore, CA (US); Stefan Drapatz, Neubiberg (DE); Markus R. Decker, Cupertino, CA (US)

Correspondence Address: MORRISON & FOERSTER LLP, 425 MARKET STREET, SAN FRANCISCO, CA, 94105-2482, US

(73) Assignee: PDF Solutions, Inc., San Jose, CA (US)

(21) Appl. No.: 11/438,777

(22) Filed: May 22, 2006

(51) Int. Cl. G11C 5/02

(52) U.S. Cl. 365/51

(57) ABSTRACT

For methods of creating pluralities of semiconductor test structure layouts from a graphical specification, systems include a GUI to draw objects representing shapes of such layout, and to parameterize those objects to size and interrelate those objects. The GUI supports placement of cells in hierarchical layers. The graphical specification is parsed into an ASCII descriptor file from which node information is extracted and connection information among nodes preserved in separate graphs for an X direction and a Y direction of the layout. That node and connection information is further processed to obtain equations having variables (parameters) that relate points in the layout a defined point, and those equations used in forming source code that can be executed with values for the variables in the source code.

### BACKGROUND

1. Field

The present application relates to graphical specification of semiconductor structures, and, more particularly, to graphically specifying and parameterizing and automating layout generation for semiconductor test structures.

2. Related Art

Circuits formed with semiconductors structures may be fabricated using, for example, a lithography process involving masks that specify geometric designs that should be created at each layer of a plurality of layers in the semiconductor structures. Together, the masks specify a layout for the semiconductor structures for a particular circuit. The layout may comprise a number of shapes connected and arranged with respect to each other at a number of different layers. The connection and arrangement of theses shapes and the layers at which these shapes are disposed define the electrical function of one or more circuits implemented in the layout. Layout for a particular circuit is typically process dependent. Design rules specify how shapes should relate to each other in a given process or a variant thereof. Thus, where a particular layout designed for one process is to be used in a different process, the layout often has to be re-designed. Additionally, a given layout may be repeated within a given process to vary certain dimensions of the structures. Creating many variations of dimensions of a common semiconductor structure is common for semiconductor structures designed to be used for automated testing and characterization of the process used to form those structures.

Test structures are used for debugging a semiconductor fabrication process. Redesigning layout for such test structures has often been done manually. However, drawing shapes comprising a layout is a process easily prone to errors. This situation gave rise to layout automation methodologies. One such automation methodology is called “PCELLS” (parameterized cells) and was developed by Cadence Design Systems, Inc., San Jose, Calif. A “pcell” in PCELLS is a programmable layout, and allows a user to specify parameters for that pcell. In the particular case of a transistor, for example, transistor width and length may be specified. A pcell may be created graphically or by writing SKILL™ code.

The graphical interface (GUI) for designing pcells has limited capabilities and is useful for small designs, like single transistors. Additionally, PCELLS lacks a capability to easily reuse layout in a given design. Writing SKILL™ code to specify a pcell is also error prone and not flexible enough to realistically implement either large designs or to allow easy modification and maintenance of layout created with the code. Other approaches are based on pre-coded layout designs. Such approaches include Dolphin GDS-Compiler, Stone-Pillar, and Silicon Canvas. Such pre-coded layout designs often operate at the level of small cells, such as single transistors or functional blocks like a ring oscillator. Such approaches also do not generally provide, to the degree desired, ease of design, portability, and ease of maintenance of layouts created with those approaches. Therefore, there is a need for another approach to a system for generating layout of semiconductor structures.

### SUMMARY

Aspects of an exemplary method for creating layouts for semiconductor test structures, as presented herein, include creating a first cell, and drawing one or more objects in the first cell. The one or more objects represent shapes of features for a semiconductor test structure. The method also includes, after drawing the one or more objects in the first cell, defining one or more parameters for each of the one or more objects drawn in the first cell. In a particular example, the method includes defining a test structure layout using a tree of cells that includes one or more instances of the first cell, and creating machine readable code using the tree of cells. Thereafter, the machine readable code may be executed with different values for the one or more parameters of the one or more objects drawn in the first cell to generate a set of different test structure layouts.

The exemplary method may further include creating a second cell and drawing two or more objects in the second cell. Each of the two or more objects represent shapes of features for a semiconductor test structure, and the first cell may be used as at least one of the two or more objects in the second cell. The method further comprises, after drawing the two or more objects in the second cell, defining one or more parameters for each of the two or more objects drawn in the second cell. The one or more parameters of an object corresponding to the first cell define a relationship between the object corresponding to the first cell and another object in the second cell.

Additionally, the tree of cells may include one or more instances of the second cell. Different values for the one or more parameters of the two or more objects drawn in the second cell are used in executing the machine readable code to generate the set of different test structure layouts.

Aspects of another exemplary method for creating layouts for semiconductor test structures, include creating a first cell, drawing one or more objects in the first cell. The one or more objects represent shapes of features for a semiconductor test structure. After drawing the one or more objects in the first cell, the method includes defining one or more parameters for each of the one or more objects drawn in the first cell, creating a second cell, and drawing one or more objects in the second cell. Each of the one or more objects of the second cell represent shapes of features for a semiconductor test structure and the first cell is used as at least one of the one or more objects in the second cell. Thereafter, the machine readable code may be executed with different values for the one or more parameters of the one or more objects drawn in the first cell to generate a set of different test structure layouts.

Such method steps may be executed in whole or in part by various parties, for example, a tree of cells may be formed by a first entity and a second entity may use that tree of cells as described herein.

### BRIEF DESCRIPTION OF DRAWINGS

FIG. 1A illustrates a top view of an example test structure called a via chain;

FIG. 1B illustrates a cross section view of the via chain;

FIG. 2 illustrates a high level organization of a system implementing methods according to aspects described herein;

FIG. 3 illustrates a particular implementation of a system implementing methods according to aspects described herein;

FIG. 4 illustrates a conceptual dataflow in implementing presently described aspects of such exemplary methods;

FIGS. 5A-D illustrates various tools that are used to graphically input boundaries describing objects in a cell and to parameterize those objects with respect to each other and to the cell;

FIG. 6A illustrates further aspects of graphically editing and parameterizing objects in a cell;

FIG. 6B illustrates replicating the object created in FIG. 6B in a cell at a higher layer of hierarchy;

FIG. 7A illustrates hierarchy lines used for simplifying complicated hierarchical drawings;

FIG. 7B illustrates a cell having instantiated objects with hierarchy lines;

FIG. 8 illustrates an instance array of a cell and how instances of a given cell may be parameterized with respect to each other and to the cell;

FIG. 9 illustrates over and under parameterization of an object in a cell;

FIG. 10 illustrates a tree of cells, one of which is a cell called “runner”;

FIG. 11 illustrates another cell called “runner”;

FIG. 12 illustrates steps of an exemplary method described with respect to the cell “runner”; and

FIG. 13 illustrates a graph created from information extracted from the graphical specification of the cell “runner.”

### DETAILED DESCRIPTION

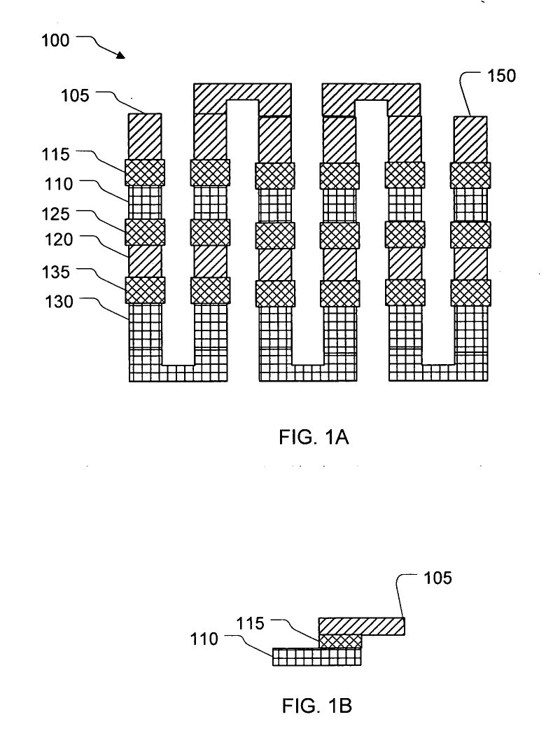

FIG. 1A illustrates a top view of layout for a via chain 100. Via chain 100 comprises a connector 105 in a top metal layer, connected by via 115 to a metal run 110 in a lower metal layer. Metal run 110 in turn is connected to a metal run 120 in the top metal layer through via 125. In turn, metal run 120 connects with metal run 130 through via 135. Ultimately, via chain 100 terminates at connector 150. Thus, via chain 100 is, when formed on a semiconductor wafer, an interconnected series of metal lines running through two separate layers of metal (other via chains can include metal runs in more than two layers), where those layers are connected by vias.

As such, via chain 100 allows a process to be tested and examined for via alignment with metal layers, for example. This testing may proceed by applying a voltage across connector 105 and connector 150 and measuring a current flow through via chain 100. Variations in current from what is expected may be indicative of alignment problems of the via layer with either the top or lower metal layers. Metal layers may be varied in width and in length to accomplish other testing goals. For example, metal run 110 may be made twice as long as metal run 120. FIG. 1B illustrates a portion of via chain 100 in cross-section. As is illustrated in FIG. 1B, connector 105 connects through via 115 to the metal run 110.

It should be recognized that via chain 100 need not be limited to metal. For example, via chain 100 can be a poly active chain with contacts.

As can be seen in via chain 100 test structures may be repetitive, and may be comprised of repetitive building blocks. Such test structures may lend themselves to a hierarchical design process, as will be further described herein. Additionally, even in a relatively simple test structure, such as via chain 100, there are many variations on the basic test structure that may be useful for different purposes. It would be useful to have a methodology for creating those variations using an automated and user friendly process, rather than by creating those variations manually or with minimal computer assistance.

A Layout ComPiler (LCP) according to exemplary aspects herein provides such a methodology. The LCP may be used to graphically specify parameterized test structure layout, and to generate computer executable code (a generator module) from that graphical specification that, with input from a database of information can produce various layouts of the graphically designed test structure. The steps of the LCP design flow include setup, graphical design, converting that design to ASCII specification, converting the ASCII specification to node graphs, converting those node graphs to coordinate lists, and then converting those coordinate lists to source code that with input from a database can be used to generate a plurality of layouts.

In the present example, before a particular graphical design entry is started, some initialization and setup of the process and environment may be done. In the present example, one or more layers may be created. These layers can be used to capture and display measure and guide lines that parameterize objects and interrelationships between objects in a cell of a test structure and between cells of a test structure. These layers may be automatically created in the LCP system. In the present example, when these layers are initially created, they are not necessarily associated with a particular technology or process. Instead, they are generic and act as placeholders until a technology or process is later specified, such as during execution of the source that is eventually generated based on these initial layers.

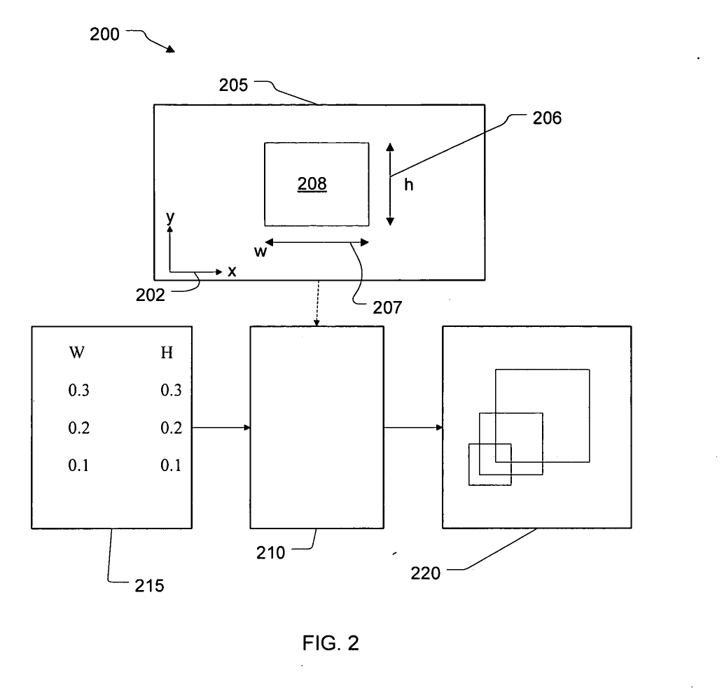

Turning to FIG. 2, there is conceptually illustrated an LCP system 200 flow for graphically designing, using hierarchical tools, test structures that may be ported to various processes or used as cells (components) of other test structures. Functions and features of the LCP will be illustrated with examples, including that of via chain 100 (FIG. 1). A graphical layout designer 205 is provided for graphical parameterization and entry of test structures, where parameters are used to define dimensions of the test structure being entered, for example, height parameter 206 and width parameter 207 of rectangle 208 may be specified. Rectangle 208 can also be specified with respect to coordinate system 202. In this example, for illustrative purposes, FIG. 2 illustrates that layout designer 205 provides a graphical means for entry of various two dimensional objects of a cell for a semiconductor test structure. At times, the test structure may comprise only that cell. Typically however, a test structure will comprise a number of cells in the graphical methodology presented herein, as will be addressed.

The graphical layout designer 205 communicates with compiler 210, which generates source code from graphical specifications entered into designer 205. That source code generated by compiler 210 is then interfaced with a database 215 that provides values for the parameters specified in the code, which in turn came from the parameters that were graphically specified in layout designer 205 (e.g., height 206 and width 207). Database 215, for example includes a table of width and height values for the height parameter 206 and width parameter 207 of rectangle 208. The result is illustrated in layout view 220, where given the three sets of parameters for height and width from database 215, three different rectangles are thereby created for layout.

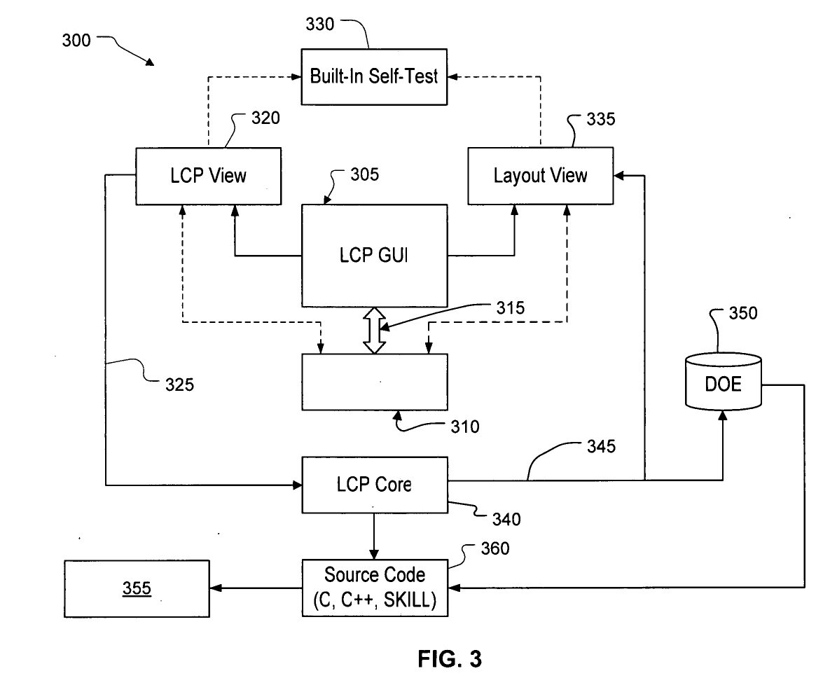

FIG. 3 illustrates a particular system 300 implementation of an LCP build from pre-existing tools and databases, such that existing tools and infrastructure can be used for implementing the methods and systems described herein.

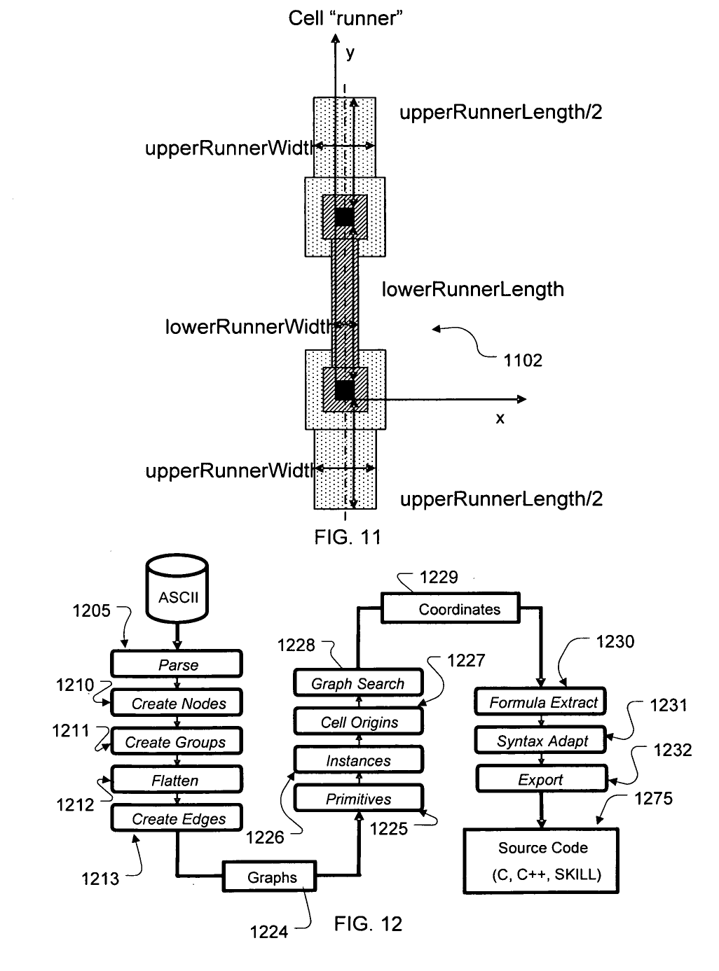

The system 300 includes a GUI 305 for graphically entering and parameterizing objects of cells for test structures. The GUI 305 communicates with database 310, in this example, using the SKILL code API. The LCP GUI 305 feeds both an LCP view 320 and a layout view 335. Each of the LCP view 320 and the layout view 335 can also communicate with database 310 for pulling information relating to cells and other information used or displayed in those respective views. From each of these views, data can be compared at built in self test 330 to ensure that the respective views are the same. The LCP view 320 provides information for generating an ASCII specification 325 of cell objects displayed in the LCP view 320. That ASCII specification 325 is input to the LCP core 340 (described in more detail with respect to FIGS. 11 and 12). The LCP core 340 may output ASCII information 345 that can be fed into layout view 335 as well as fed to DOE 350 where parameters graphically entered can be associated with values for different layouts. The LCP core 340 also outputs source code that when executed with information from the DOE 350 (such as values for parameters interrelating various aspects of the cell graphically entered in GUI 305), a number of layouts 355 may be created.

The LCP examples of FIGS. 2 and 3 may be implemented in a variety of ways, for example by code executing on a computer running a variety of operating systems, by a distributed network of computers, having GUI code executing on various clients and core 340 code executing on one or more servers. Various portions of such systems may communicate over Wide Area Network connections such as the Internet or secure tunnels through the Internet, among other communication schemes. One of ordinary skill in the art would recognize that a variety of implementations of such examples are possible and would choose an implementation for a particular purpose, such as for a particular size of organization, a particular budget, and the like.

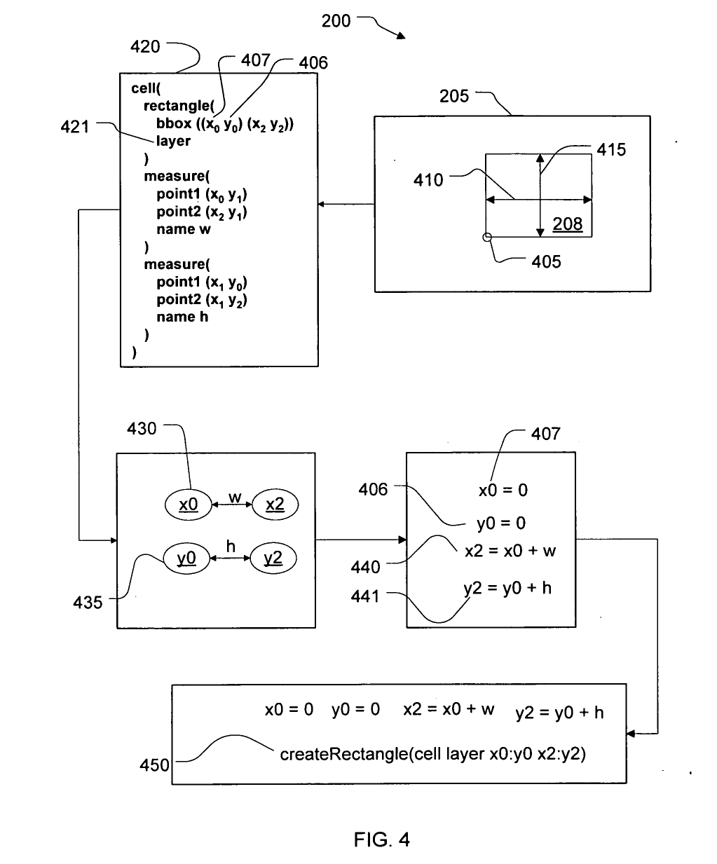

FIG. 4 illustrates in further detail how graphical specifications and parameters entered graphically may be converted into source code that can be interfaced with a database having various values for use with the graphically defined parameters. For the example of the rectangle 208 in FIG. 2, an origin 405 comprising y0 406 and x0 407 values is defined. Origin 405 may then be used to locate and position rectangle 208, as will be further described. Further, a measure line 410 may be drawn in rectangle 208 to define how width 207 (FIG. 2) of rectangle 208 may be measured. Likewise, a measure line 415 may be drawn in rectangle 208 to define how height 206 (FIG. 2) of rectangle 208 may be measured.

Once the origin, height and width of rectangle 208 are parameterized graphically, that parameterization may be used to generate an ASCII description 420 of that rectangle. As illustrated, the ASCII description includes the basic rectangle form and the nodes (x0 y0) (x2 y2) that define the rectangle by defining opposite corners of the rectangle. The ASCII description also includes layer 421 information that is derived from the graphical editing process, since the graphical editing process provides for editing of graphical shapes on a layer by layer basis. So, where the rectangle was added in a via layer, for example, then layer 421 would specify that via layer. Additionally, the measure lines 410 and 415 are described as to the names that were assigned to them (i.e., w and h) and where they begin and end. After ASCII description 420 is created, then graphs for each dimension that specify the relationship between the nodes in each dimension may then be created. For example, X graph 430 illustrates that x0 407 is related to x2 by w and Y graph 435 illustrates that y0 406 is related to y2 by h.

Thus, because there is a known relationship between nodes of each graph, coordinates of the nodes of each graph can then be extracted, and these coordinates describe the nodes by the measures that were setup in the graphical specification. Here for example, the origin 405 of rectangle 208 was defined, and then the width 207 (FIG. 2) and the height 206 (FIG. 2) were then used to define the extent of rectangle 208 by defining nodes x2 440 and y2 441. Thus, rectangle 208 is completely specified.

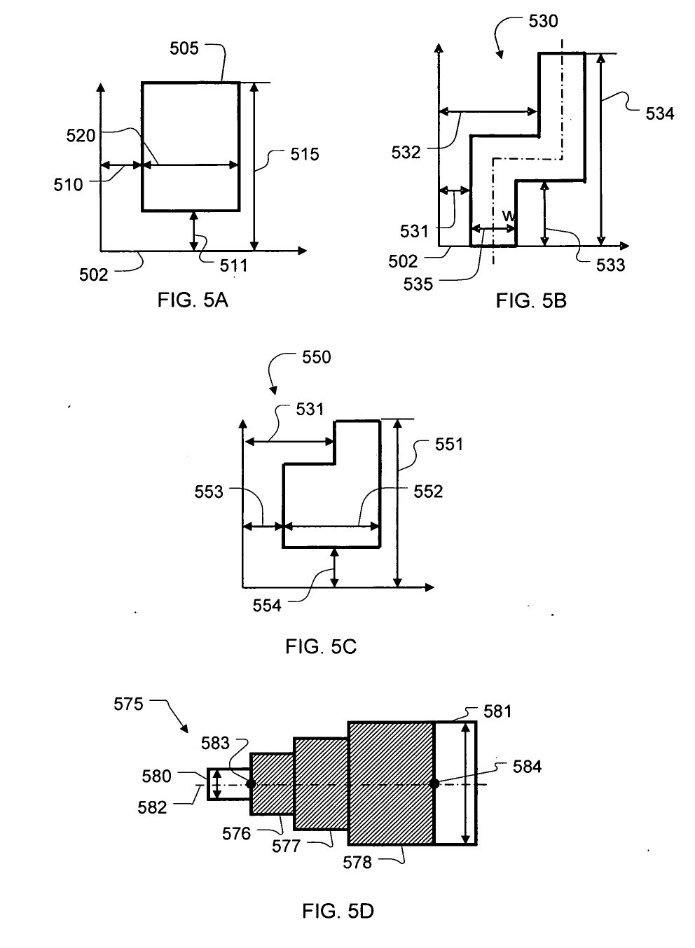

From the coordinates, source code can be generated that can be interpreted as calling for creation of a rectangle at layer 421, with coordinates as defined by the equations extracted from the graphs. As illustrated, such code may include a createrectangle command 450 that includes the parameterization of the rectangle to be created. This process will be described in more detail herein. Prior to such further description, various other primitives and other functions and features available for graphically editing layers of a layout that can be used to graphically create, parameterize, and interrelate shapes are introduced in FIGS. 5-8.

FIG. 5A illustrates a rectangle 505. Rectangle 505 of FIG. 5A is used to illustrate that shapes can be parameterized in a plurality of ways. Rectangle 208 (FIG. 2) was specified with origin 405 (FIG. 4) and height 206 (FIG. 2) and width 207 (FIG. 2). By contrast, rectangle 505 is specified by specifying x0 510 and y0 511 in relation to coordinate system 502, by specifying an absolute height y1 515 from coordinate system 502, and a width 520. Other permutations of the example of FIG. 5A are possible, including that an absolute width may be specified in relation to coordinate system 502, instead of a width in relation to x0 510.

FIG. 5B illustrates creation of a path 530. Path 530 is specified by specifying b 0 531, x1 532, y0 533, and y1 534 in relation to coordinate system 502. Additionally, a width 535 of path 530 may then be specified to result in a complete parameterization of path 530. Again, such parameterizations may be conveniently be added graphically in the graphical editor such that relations between the parameters defined for any given shape more easily discerned.

FIG. 5C illustrates a polygon 550 that has an arbitrary number of sides (the polygon may be drawn side by side in the graphical editor). For the present example, polygon 550 has six sides, but may again be defined by establishing an origin at a lower left corner of the shape and additionally be a combination of absolute measurements, such as height 551, y0 origin 554, and x0 origin 553, and relative measurements, such as width 552.

As can be gleaned from the present and previous examples, the graphical editor provides a variety of means for drawing any of a variety of geometric objects and then parameterizing various dimensions of those objects, which allows a designer to design a layout that is conceptually easier to understand. For example, paths, such as path 530 are typically desired to be center aligned with other structures, and by contrast, rectangles may be arbitrarily placed for creating test structures. Additionally, although FIGS. 5A, 5B, and 5C depict shapes with Manhattan geometry, it should be recognized that the shapes can have orientations at various angles, including at arbitrary angles.

FIG. 5D illustrates a funnel 575, which is typically used for connecting paths or rectangles of different dimensions. Funnel 575 gradually steps in width from a wider end to a narrower end. Gradually stepping in width, rather than having abrupt junctions, is a desired quality for manufacturability and electrical characteristics, as is known by those of skill in the art. A useful characteristic of path 530 becomes apparent in FIG. 5D as a narrow path 580 and a wide path 581. Funnel 575 may be parameterized by specifying a start point 583 and an end point 584 along a line 582. Steps 576, 577, 578 of funnel 575 may then be parameterized according to a formula. Although line 582 appears as a centerline in FIG. 5D, it should be recognized that line 582 need not be the centerline of funnel 575.

Such objects are exemplary of those that may be graphically specified in the graphical editor described herein, and a variety of other shapes and design parameter methodologies may be comprehended from these examples. Now, description will be provided as to how various geometrical shapes that were parameterized may be combined, and repeated, such that interrelationships between and among those geometrical shapes is completely specified in multiple layers of hierarchy.

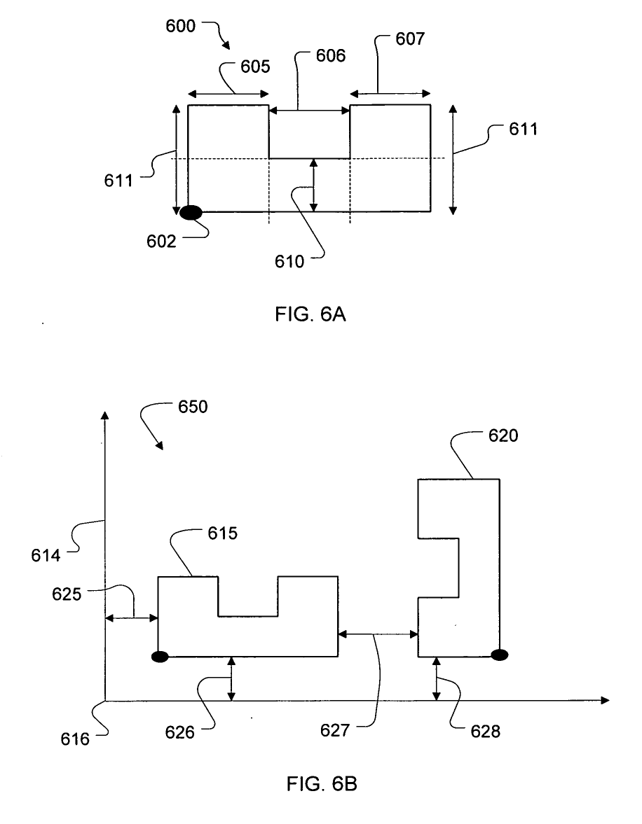

FIG. 6A illustrates a U-shaped object 600 that is parameterized by an origin 602 (x0, y0), by a series of widths 605-607 that parameterize respective partial widths of the U shape, by a first height 610 that parameterizes a height of a bottom of the U shape with respect to the origin, and by a second height 611 that parameterizes a height of the top of the U shape with respect to the origin. As can be discerned, the combination of these parameters completely specifies object 600.

Object 600 can then be instantiated multiple times as illustrated in FIG. 6B with instance 615 and instance 620 provided in cell 650. As is illustrated in FIG. 6B, a location of instance 615 may be specified by distances 625 and 626 from an origin 616 of the coordinate system 614. Instance 620 was rotated before placement. As is illustrated, a distance 627 between instance 615 and instance 620 may be specified, and a distance 628 of instance 620 from origin 616 in the y dimension may also be specified. As such, an object that includes instance 615 and 620 is completely parameterized by the parameterization of object 600 in FIG. 6A and by the additional interrelational parameters added in FIG. 6B. Thus, a hierarchical abstraction has been made of the layout such that each object need not be redrawn, with dimensions of each object specified at the time of drawing, but instead parameters may be provided values specified by referencing databases during execution of code generated from the graphical specification (as described in relation to FIG. 4). Although FIG. 6B depicts instance 620 rotated about 90 degrees with respect to instance 615, it should be recognized that instance 620 can be rotated at any angle with respect to instance 615. Also, it should be recognized that instance 620 can be created as a horizontal or vertical mirror image of instance 615.

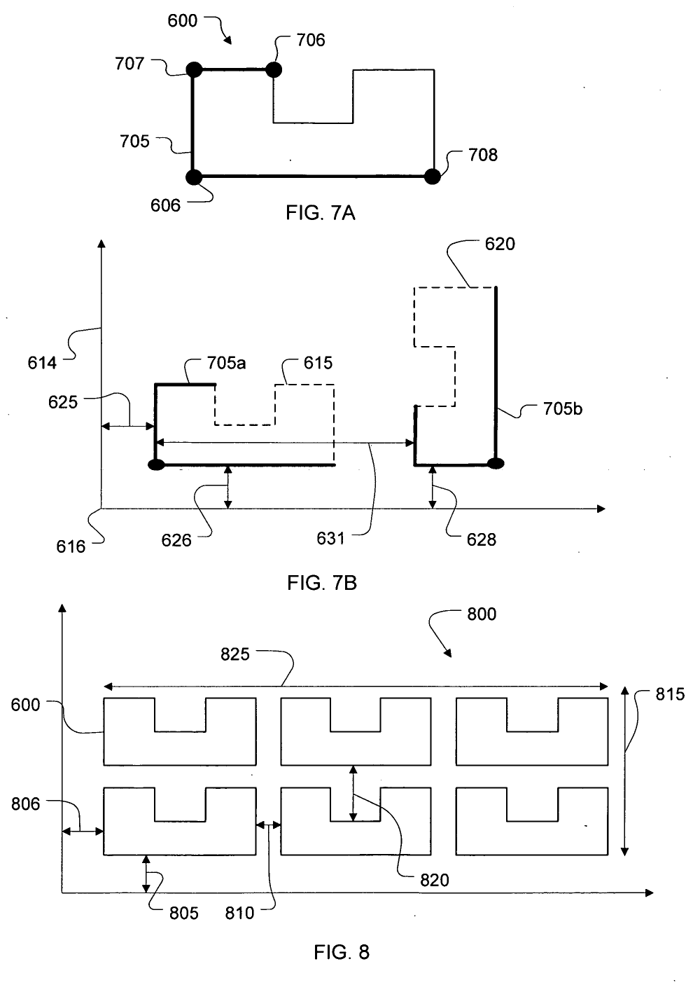

FIGS. 7A and 7B illustrate a useful aspect of the graphical editor that aids in visualization of objects during hierarchical design creation. Starting from the object 600, a designer may specify a hierarchy line 705 that extends from node 706 to node 708 through nodes 707, and 606 (origin). Then, when object 600 is instantiated into instance 615 and instance 620 (FIG. 6B) into a higher level of hierarchy in FIG. 7B, hierarchy line 705 remains visible in that level (as hierarchy lines 705a and 705b). Parameters 625, 626, 631, and 628 that position instance 615 and instance 620 in the higher level of hierarchy with respect to that origin 616 of coordinate system 614 and with respect to each other may then be specified with respect to those hierarchy lines 705a and 705b. This is advantageous where many objects are provided at a given hierarchy level so that not all the lines of any given shape are treated the same. For example, objects in one layer may be limited to being snapped onto lines in another layer that have been specified as being hierarchy lines.

FIG. 8 illustrates another aid for graphical creation of a layout provided in exemplary aspects. As discussed with respect to via chain 100 (FIG. 1), semiconductor structures, and in particular test structures, are generally repetitive. Thus, a mechanism to provide easy duplication of shapes for such test structures is valuable. A cell 800 illustrates that object 600 has been duplicated using an instance array function. The instance array function provides for the graphical specification of an origin 805 and 806 of a first instance of object 600, a spacing between instances in a given row (e.g., a spacing 810 between first instance 805 and second instance 806), a spacing 820 between rows, a total height 815, and a total width 825. Given that the width of each object 600 was previously parameterized, and a spacing 810 between each object and a spacing 820 between rows of objects are known, then a total number of objects can be calculated and placed automatically by the graphical editor, as illustrated in FIG. 8. Such an example may be called an instance array. Instance arrays may be laid out dynamically based on dimensions of an object to be laid out and absolute dimensions for the area to be occupied by an array of instances of the object. Alternatively, row and column numbers may also be specified.

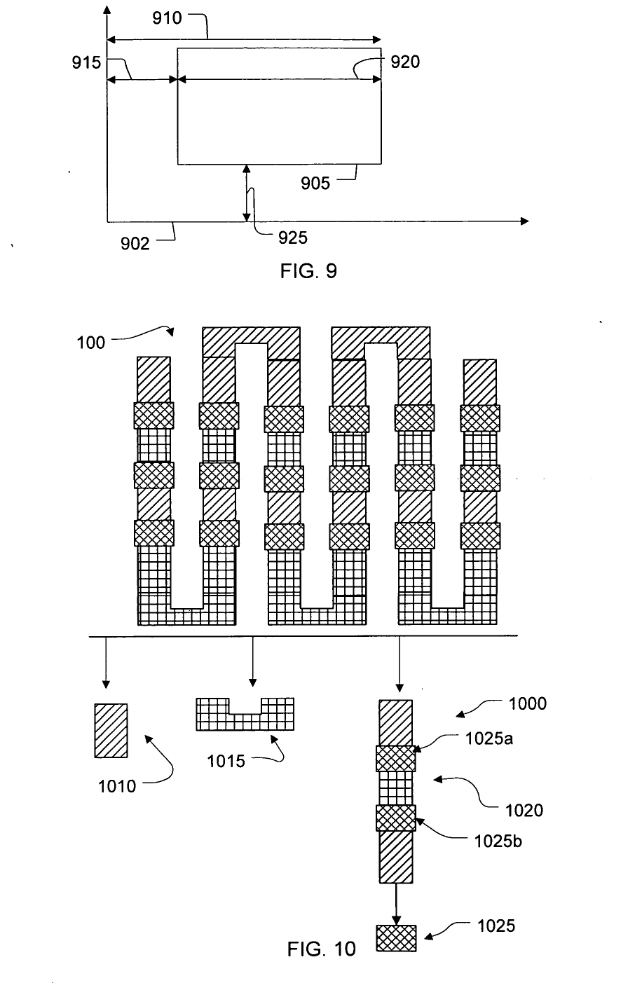

FIG. 9 illustrates another design aid that automates determining whether a given object is completely parameterized, rather than overspecified or underspecified. In FIG. 9, rectangle 905 was drawn, measure line 915 was added to parameterize the left side of rectangle 905 with respect to the coordinate system 902. Measure line 920 was added to parameterize a width of rectangle 905. The combination of measure line 915 and measure line 920 completely specify parameterize an X dimension of rectangle 905.

However, measure line 910 was added which parameterizes a right side of rectangle 905 with respect to coordinate system 902. Thus, the X dimension is now over specified because there are two separate parameters indicating where a right side of rectangle 905 should be drawn. One such parameter must be deleted. By contrast, a bottom part of rectangle 905 was parameterized with respect to coordinate system 902 by measure line 925. However, there is no measure line indicating where the top of the rectangle 905 should be placed, either relatively to the bottom of rectangle 905 or to coordinate system 902. Another parameter must be added to completely specify the height aspect of rectangle 905.

Other functionality useful for graphically entering and parameterizing objects in test structure cells include functionality for counting objects, such as vias, devices, gate perimeters, source/drain areas or ratios of gate emitter areas and the like. Such functionality can also be more generalized into user defined functions that can be used to implement more complicated design features such as shielding for paths and the like.

Once the test structure is completed, a functionality called check and save functionality may be used to verify that the graphical layout does not have under or over specification of objects. The check and save functionality may proceed hierarchically from a lower level of hierarchy and move upward through the levels.

Ultimately, a user completes a layout of objects to form cells for a test structure, and those cells may be instantiated a number of times, and each such instance of each cell may be parameterized in a given layer of hierarchy to specify interrelationships among those instances and to a defined point in the layer (e.g., an origin of the layer). That layer of hierarchy may then be instantiated in a yet higher layer of hierarchy. The result may be described as a tree of cells where each layer describes how the cell is instantiated at higher levels of hierarchy to form a test structure.

Returning to via chain 100, a tree of cells 1000 is illustrated in FIG. 10. Tree of cells 1000 hierarchically describes the cells that are instantiated as objects in each higher layer of hierarchy in via chain 100. A lowest level of hierarchy is evident in via cell 1025. Via cell 1025 is instantiated twice as via 1025a and 1025b in runner cell 1020. Runner cell 1020 in turn is instantiated numerous times in via chain 100. Additionally, a turn 1015 is also instantiated numerous times in via chain 100. Similarly, a connector 1010 is instantiated at a beginning and an end of via chain 100 as connectors 105 and 150 (FIG. 1). As is illustrated, tree of cells 1000 describes the components that are used to make up via chain 100, where those components can be rotated and repeated and otherwise positioned to form the structure desired.

To further illustrate how a cell may be processed, the remainder of the description focuses on runner cell 1020. As briefly discussed with respect to FIGS. 2 and 3, after graphical entry of a test structure—for this example, runner cell 1020—that test structure is processed to generate an ASCII descriptor file for further processing. The ASCII descriptor file may take any number of formats, so long as the parameterizing information graphically entered is represented.

An example of an ASCII format is presented in Table 1, below. The ASCII format presented in Table 1 corresponds to runner cell 1102 depicted in FIG. 11. The flow that will be discussed is illustrated in FIG. 12.

TABLE 1
ASCII input file for cell “runner”

```
cell “runner” (
    rectangle(
        bbox ((−0.02 1.44) (0.26 1.84))
        layer “upperLayerName”
    )
    rectangle(
        bbox ((−0.02 −0.48) (0.26 −0.08))
        layer “upperLayerName”
    )
    rectangle(
        bbox ((0.02 0.28) (0.22 1.08))
        layer “lowerLayerName”
    )
    guide(
        point1 (0.12 −0.5)
        point2 (0.12 1.88)
    )
    instance(
        origin (0.0 1.12)
        bbox ((−0.08 1.04) (0.32 1.44))
        cell “via”
        rotation “R0”
        rows 1
        cols 1
        rowPitch 0.0
        colPitch 0.0
    )
    instance(
        origin (0.0 0.0)
        bbox ((−0.08 −0.08) (0.32 0.32))
        cell “via”
        rotation “R0”
        rows 1
        cols 1
        rowPitch 0.0
        colPitch 0.0
    )
    measure(
        point1 (0.44 0.24)
        point2 (0.44 1.12)
        name “lowerRunnerLength”
    )
    measure(
        point1 (0.2 1.36)
        point2 (0.2 1.84)
        name “upperRunnerLength/2.0”
    )
    measure(
        point1 (0.21 0.0)
        point2 (0.21 −0.48)
        name “upperRunnerLength/2.0”
    )
    measure(
        point1 (−0.02 1.61)
        point2 (0.26 1.61)
        name “upperRunnerWidth”
    )
    measure(
        point1 (−0.02 −0.2)
        point2 (0.26 −0.2)
        name “upperRunnerWidth”
    )
    measure(
        point1 (0.02 0.67)
        point2 (0.22 0.67)
        name “lowerRunnerWidth”
    )
)
```

An aspect to note with the ASCII descriptor file is that objects drawn at a top level of hierarchy, e.g., the “rectangles” and the “guides” at the beginning of the file include physical description information. By contrast, instantiations of cells created in lower levels of hierarchy (e.g., the instance of the cell “via” near the bottom of the first column) include information for positioning and sizing the cell within the top level of hierarchy, and information for repeating (or not repeating as the case may be) the cell as an instance array.

Now, aspects of turning this ASCII input file into a graph will be addressed with respect to FIG. 12 and Table 2. First, the ASCII input file is parsed at 1205 (FIG. 12). This parsing extracts the relevant characteristics of the features described in the ASCII file; these characteristics include the instances of cells, rectangles, size, placement information and the like. The parsing process adapts the ASCII form that can more easily be edited by humans into a form that can be more easily operated on by machines.

Next, nodes are created (1210 in FIG. 12) to model the interconnection of the elements described in the ASCII file. These nodes include nodes in both the X and the Y direction. At least in the present example, the nodes for each direction (X and Y) are kept separate. Table 2 thus illustrates nodes for the X direction extracted from the parsed ASCII file of Table 1 for each element of cell runner at the highest level of hierarchy. Node 1, by example, includes a left edge of the first upper layer metal run, node 2 includes a right edge of that upper layer metal run, nodes 5 and 6 correspond to the second upper metal layer run, while nodes 3 and 4 correspond to the left and right sides of the lower metal layer run, respectively. Other nodes included in Table 2 include the origin at node 8 and the center guideline (node 7).

TABLE 2
X-Nodes of cell “runner”

| Node | Value | From | To |
|---|---|---|---|
| 1 | −0.02 | 1.44 | 1.84 |
| 2 | 0.26 | 1.44 | 1.84 |
| 3 | 0.02 | 0.28 | 1.08 |
| 4 | 0.22 | 0.28 | 1.08 |
| 5 | −0.02 | −0.48 | −0.08 |
| 6 | 0.26 | −0.48 | −0.08 |
| 7 | 0.12 | −0.50 | 1.88 |
| 8 | 0 | 0 | 0 |

Thereafter, groups of X nodes are created by merging edges that abut into a single node of the cell (1211 of FIG. 12). Table 3 illustrates the groups of X nodes created by this grouping process. In this particular instance, the nodes and groups do not change. However, in a more complex example, changes would be evident per the different description between nodes and groups of nodes.

TABLE 3
X-groups of cell “runner”

| Node | Value | From | To |
|---|---|---|---|
| 1 | −0.02 | 1.44 | 1.80 |
| 2 | 0.26 | 1.44 | 1.84 |
| 3 | 0.02 | 0.28 | 1.08 |
| 4 | 0.22 | 0.28 | 1.08 |
| 5 | −0.02 | −0.48 | −0.08 |
| 6 | 0.26 | −0.48 | −0.08 |
| 7 | 0.12 | −0.50 | 1.88 |
| 8 | 0 | 0 | 0 |

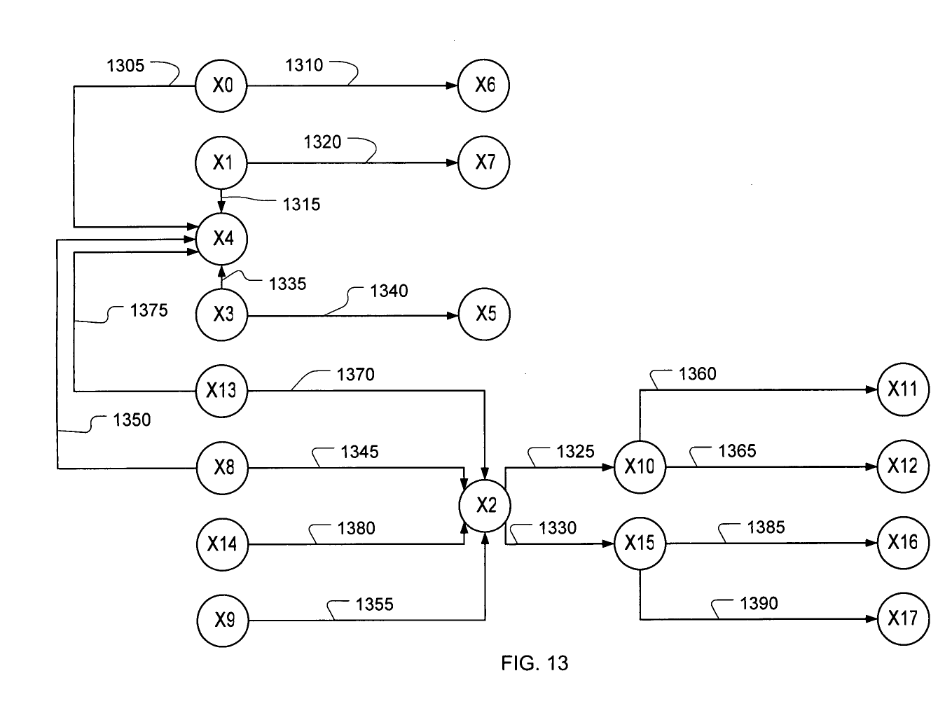

Following the grouping, the cell runner is flattened at 1212 (FIG. 12), including that the instances of the cell via are flattened, thereby incorporating their nodes into a description of the nodes of the entire cell runner. The results are presented in Table 4, below. Here, for example, nodes 8 and 9 correspond to a left side of the upper via (describe an inner and outer edge of cell via) while nodes 11 and 12 correspond to the right side. Nodes 13-16 correspond to the lower via. Thus, at Table 4, there is a description of the nodes without hierarchy for the cell runner. These nodes will account for nodes in a graph that are connected by measure line information extracted from the ASCII file, as will be described below with respect to Table 5, and FIG. 13.

TABLE 4
X-nodes of cell “runner” after flattening

| Node | Value | From | To |
|---|---|---|---|
| 0 | −0.02 | −0.48 | −0.08 |
| 1 | −0.02 | 1.44 | 1.84 |
| 2 | 0.00 | 0.00 | 1.36 |
| 3 | 0.02 | 0.28 | 1.08 |
| 4 | 0.12 | −0.50 | 1.88 |
| 5 | 0.22 | 0.28 | 1.08 |
| 6 | 0.26 | −0.48 | −0.08 |
| 7 | 0.26 | 1.44 | 1.84 |
| 8 | −0.08 | 1.04 | 1.44 |
| 9 | −0.04 | 1.08 | 1.40 |
| 10 | 0.24 | 1.12 | 1.36 |
| 11 | 0.28 | 1.08 | 1.40 |
| 12 | 0.32 | 1.04 | 1.44 |
| 13 | −0.08 | −0.08 | 0.32 |
| 14 | −0.04 | −0.04 | 0.28 |
| 15 | 0.24 | 0.00 | 0.24 |
| 16 | 0.28 | −0.04 | 0.28 |
| 17 | 0.32 | −0.08 | 0.32 |

After the cell runner is flattened, edges are created at 1213 (FIG. 12). As illustrated in Table 5, and in Table 1 with the original ASCII text, the measure lines are illustrated, but now the nodes which are interrelated are mapped to each measureline and referenced in FIG. 13 in a graph created based on Table 5 (1224 in FIG. 12) that shows the interrelationship among nodes in Table 5.

TABLE 5
Measure lines (edges of graph) connection the X-graph of cell “runner

| | | | Reference in |
|---|---|---|---|
| From | To | Measureline | FIG. 13 |
| X0 | X4 | upperRunnerWidth/2.0 | 1305 |
| X0 | X6 | upperRunnerWidth | 1310 |
| X1 | X4 | upperRunnerWidth/2.0 | 1315 |
| X1 | X7 | upperRunnerWidth | 1320 |
| X2 | X10 | viaSize | 1325 |
| X2 | X15 | viaSize | 1330 |
| X3 | X4 | lowerRunnerWidth/2.0 | 1335 |
| X3 | X5 | lowerRunnerWidth | 1340 |
| X8 | X2 | viaUpperLayerOverlap | 1345 |
| X8 | X4 | (viaSize + 2 * viaUpperLayerOverlap)/2.0 | 1350 |
| X9 | X2 | viaLowerLayerOverlap | 1355 |
| X10 | X11 | viaLowerLayerOverlap | 1360 |
| X10 | X12 | viaUpperLayerOverlap | 1365 |
| X13 | X2 | viaUpperLayerOverlap | 1370 |
| X13 | X4 | (viaSize + 2 * viaUpperLayerOverlap)/2.0 | 1375 |
| X14 | X2 | viaLowerLayerOverlap | 1380 |
| X15 | X16 | viaLowerLayerOverlap | 1385 |
| X15 | X17 | viaUpperLayerOverlap | 1390 |

Based on the graph of FIG. 13, processing of cell runner may continue with formation of primitives at step 1225 (FIG. 12). The process continues with the data from Table 5, which includes a complete graph database of the X nodes of the cell “runner”. To create primitives, the links to the nodes of each primitive are stored. To create each instance formula (step 1226), the link to the origin of each instance is stored. Then, at step 1227 the link to the origin of each cell is stored. At 1228, the corresponding nodes in the graph are used to provide a formula for all the primitive nodes and instance origins, and further the primitive and instances nodes are searched with a graph search algorithm. The result, illustrated at 1229 is coordinates for each point defining a portion of the cell “runner.”

From the coordinates at 1229, a formula is extracted at 1230. A further example of formula extracted is found in FIG. 4, as well. Work is done on the formula at 1231 to make the formula adapted for a particular syntax (format) and then the formula are exported as source code to arrive at the source code result 1275.

Although various exemplary embodiments have been described, various modifications can be made without departing from the spirit and/or scope of the present invention. Therefore, the present invention should not be construed as being limited to the specific forms shown in the drawings and described above.

We claim:

1. A method of creating layouts for semiconductor test structures, the method comprising:
creating a first cell;
drawing one or more objects in the first cell, wherein the one or more objects represent shapes of features for a semiconductor test structure;
after drawing the one or more objects in the first cell, defining one or more parameters for each of the one or more objects drawn in the first cell;
defining a test structure layout using a tree of cells that includes one or more instances of the first cell;
creating machine readable code using the tree of cells; and
executing the machine readable code with different values for the one or more parameters of the one or more objects drawn in the first cell to generate a set of different test structure layouts.

2. The method of claim 1, further comprising:
creating a second cell;
drawing two or more objects in the second cell, wherein the two or more objects represent shapes of features for a semiconductor test structure, and wherein the first cell is used as at least one of the two or more objects in the second cell; and
after drawing the two or more objects in the second cell, defining one or more parameters for each of the two or more objects drawn in the second cell,
wherein the one or more parameters of an object corresponding to the first cell defines a relationship between the object corresponding to the first cell and another object in the second cell,
wherein the tree of cells includes one or more instances of the second cell, and
wherein different values for the one or more parameters of the two or more objects drawn in the second cell are used in executing the machine readable code to generate the set of different test structure layouts.

3. The method of claim 2, further comprising:
drawing two or more hierarchy lines in the first cell, wherein the two or more hierarchy lines mark two or more objects drawn in the first cell, and wherein the two or more hierarchy lines are adapted to be referenced when the first cell is used in the second cell.

4. The method of claim 1, wherein the one or more objects include lines, paths, rectangles, and polygons.

5. The method of claim 1, wherein the first cell includes an origin of the cell, and wherein the one or more objects include a guideline, a split-line, an instance, and an array, wherein the guideline is an extension of an object's edge, wherein the split-line is an additional reference line of an object, wherein the instance is a previously created cell, and wherein the array includes multiple instances arranged in rows and columns.

6. The method of claim 1, wherein the one or more objects are drawn in an object layer in the first cell, and wherein the object layer is defined by a variable that is set to a mask preparation layer as the machine readable code is executed.

7. The method of claim 1, wherein the one or more parameters are assigned to measure lines drawn in the first cell, wherein the measure lines define one or more dimensions of an objects or one or more distances between objects.

8. The method of claim 1, wherein the one or more parameters are defined as:
a name referring to a variable which will be set to a physical dimension during execution of the machine readable code;
a parameter defining a reference, wherein the reference is a distance or dimension between objects in the same cell or objects defined in another cell;
a parameter defining a fixed physical dimension; or
a parameter defining a formula, wherein the formula includes variables, references, or fixed physical dimensions.

9. The method of claim 1, wherein creating machine readable code further comprises:
creating a graph associated with the tree of cells, the graph including nodes and links, wherein the nodes are associated with objects, and wherein the links are associated with parameters;
converting the nodes and links into mathematic expressions; and
converting the mathematic expressions into machine readable code.

10. The method of claim 9, further comprising:
evaluating the graph for over specification and under specification.

11. The method of claim 1, further comprising:
processing a wafer to form a test structure on the surface of the wafer in accordance with one of the set of different test structure layouts.

12. The method of claim 11, wherein processing a wafer further comprises:
simulating a test structure to be formed on the surface of the wafer using one of the set of different test structure layouts.

13. A method of creating layouts for semiconductor test structures, the method comprising:
creating a first cell;
drawing one or more objects in the first cell, wherein the one or more objects represent shapes of features for a semiconductor test structure;
after drawing the one or more objects in the first cell, defining one or more parameters for each of the one or more objects drawn in the first cell;
creating a second cell;
drawing one or more objects in the second cell, wherein the one or more objects represent shapes of features for a semiconductor test structure, wherein the first cell is used as at least one of the one or more objects in the second cell;
after drawing the one or more objects in the second cell, defining one or more parameters for each of the one or more objects drawn in the second cell;
defining a test structure layout using a set of cells that includes one or more instances of the first cell and the second cell;
creating machine readable code using the set of cells; and
executing the machine readable code with different values for the one or more parameters of the one or more objects drawn in the first and second cells to generate a set of different test structure layouts.

14. The method of claim 13, wherein the set of cells are arranged as a tree structure.

15. A method of creating layouts for semiconductor test structures, the method comprising:
obtaining a test structure layout defined using a tree of cells, the tree of cells including at least one instance of a first cell, the first cell having drawn therein one or more objects representing shapes of features for a semiconductor test structure, and wherein each of the one or more objects is associated with one or more parameters;
creating machine readable code from the test structure layout; and
executing the machine readable code with different values for the one or more parameters of the one or more objects drawn in the first cell to generate a set of different test structure layouts.

16. A computer-readable medium containing instructions which, when executed by a computer, cause the computer to create layouts for semiconductor test structures, the computer-readable medium including at least instructions for:
obtaining a test structure layout defined using a tree of cells, the tree of cells including at least one instance of a first cell, the first cell having drawn therein one or more objects representing shapes of features for a semiconductor test structure, and wherein each of the one or more objects is associated with one or more parameters;
creating machine readable code from the test structure layout; and
executing the machine readable code with different values for the one or more parameters of the one or more objects drawn in the first cell to generate a set of different test structure layouts.

17. A system to create layouts for semiconductor test structures, the system comprising:
a graphical layout designer configured to be used to:
create a first cell;
draw one or more objects in the first cell, wherein the one or more objects represent shapes of features for a semiconductor test structure;
after the one or more objects are drawn in the first cell, define one or more parameters for each of the one or more objects drawn in the first cell; and
define a test structure layout using a tree of cells that includes one or more instances of the first cell;
a database having different values for the one or more parameters of the one or more objects drawn in the first cell; and
a compiler connected to the graphical layout designer and the database, wherein the compiler is configured to generate machine readable code using the tree of cells, and wherein the compiler is configured to execute the machine readable code with the different values for the one or more parameters in the database to generate a set of different test structure layouts.

18. A system to create layouts for semiconductor test structures, the system comprising:
a graphical layout designer configured to be used to
create a first cell;
draw one or more objects in the first cell, wherein the one or more objects represent shapes of features for a semiconductor test structure;
after the one or more objects are drawn in the first cell, define one or more parameters for each of the one or more objects drawn in the first cell;
create a second cell;
draw one or more objects in the second cell, wherein the one or more objects represent shapes of features for a semiconductor test structure, wherein the first cell is used as at least one of the one or more objects in the second cell;
after the one or more objects are drawn in the second cell, define one or more parameters for each of the one or more objects drawn in the second cell; and
define a test structure layout using a set of cells that includes one or more instances of the first cell and the second cell;
a database having different values for the one or more parameters of the one or more objects drawn in the first and second cells; and
a compiler connected to the graphical layout designer and the database, wherein the compiler is configured to generate machine readable code using the set of cells, and wherein the compiler is configured to execute the machine readable code with the different values for the one or more parameters in the database to generate a set of different test structure layouts.
